(19) United States
(12) Patent Application Publication
(10) Pub. No.: US 2025/0167148 A1
(43) Pub. Date: May 22, 2025

(54) MANUFACTURING METHOD OF AN ELECTRONIC CIRCUIT COMPRISING CONTACT PADS

(71) Applicant: STMicroelectronics International N.V., Geneva (CH)

(72) Inventors: Pierre BAR, Grenoble (FR); Hugo AUDOUIN, Grenoble (FR)

(73) Assignee: STMicroelectronics International N.V., Geneva (CH)

(21) Appl. No.: 18/939,363

(22) Filed: Nov. 6, 2024

(30) Foreign Application Priority Data
Nov. 17, 2023 (FR) 2312608

(51) Int. Cl. H01L 23/00

(52) U.S. Cl. CPC H01L 24/05; H01L 24/03; H01L 2224/0226; H01L 2224/03011; H01L 2224/0381; H01L 2224/0382; H01L 2224/05083; H01L 2224/05124; H01L 2224/05166; H01L 2224/05181; H01L 2224/05624; H01L 2224/05687

(57) ABSTRACT

The present description concerns a method of manufacturing an electronic circuit comprising, in the order, the forming on a semiconductor substrate comprising a surface of at least one conductive pad extending over the surface and having sides inclined with respect to the surface, the forming of a first insulating layer on the pad, the deposition of a resin layer and the forming of an opening in the resin layer exposing the entire pad, the plasma etching of the first insulating layer in the opening, which results in the forming of first compounds on the etched edges of the first insulating layer and of second compounds on the pad, the removal of the resin layer, the removal of the first compounds, the removal of the second compounds, and the forming of a second insulating layer on the pad.

### CROSS-REFERENCE TO RELATED APPLICATION(S)

This application is a translation of and claims the priority benefit of French patent application number 23/12608, filed on 17 Nov. 2023, entitled “Procédé de fabrication d'un circuit électronique comprenant des plots de reprise de contact”, which is hereby incorporated by reference to the maximum extent allowable by law.

### BACKGROUND

### Technical Field

The present disclosure generally concerns the field of electronic circuits comprising contact pads, and a method of manufacturing an electronic circuit comprising contact pads.

### Description of the Related Art

An electronic circuit generally comprises at least one contact pad, made of a conductive material, for example based on aluminum, and having a contacting area intended to be connected to an external device, for example by means of an electrically-conductive wire. As an example, the contact pads can be used for the exchange of signals with the electronic circuit and/or for the electric power supply of the electronic circuit.

The contact pad is generally covered with an insulating layer having an opening etched therein to expose the contacting area of the contact pad. A disadvantage is that the etching of the insulating layer may result in the forming of fibers or filaments on the sides of the opening, which may be difficult to remove.

### BRIEF SUMMARY

Various embodiments provided herein overcomes all or part of the disadvantages of electronic circuits comprising contact pads and of methods of manufacturing such electronic circuits.

An embodiment provides a method of manufacturing an electronic circuit comprising the following steps, in the order:
a) forming on a semiconductor substrate comprising a surface of at least one electrically-conductive pad extending over the surface and having sides inclined with respect to the surface;
b) forming of a first electrically-insulating layer on the electrically-conductive pad;
c) deposition of a resin layer and forming of an opening in the resin layer exposing the entire electrically-conductive pad;
d) plasma etching of the first electrically-insulating layer in the opening, which results in the forming of first compounds on the etched edges of the first electrically-insulating layer and of second compounds on the electrically-conductive pad;
e) removal of the resin layer;
f) removal of the first compounds;
g) removal of the second compounds; and
h) forming of a second electrically-insulating layer on the electrically-conductive pad.

According to an embodiment, the electrically-conductive pad comprises aluminum.

According to an embodiment, at step d), the plasma comprises fluorine.

According to an embodiment, step g) comprises a reactive ion etching using an argon ion beam.

According to an embodiment, the minimum distance between the wall of the opening and the electrically-conductive pad is greater than the thickness of the first electrically-insulating layer.

According to an embodiment, the first electrically-insulating layer is made of a first material, for example of silicon oxynitride.

According to an embodiment, the second electrically-insulating layer is made of a second material, different from the first material, for example of aluminum oxide.

According to an embodiment, the angle of inclination of each inclined side with respect to the surface is in the range from 250 to 50°.

An embodiment also provides an electronic circuit comprising:
a semiconductor substrate comprising a surface;
an electrically-conductive pad extending over the surface and having sides inclined with respect to the surface;
a first electrically-insulating layer on the surface which surrounds the electrically-conductive pad and does not cover the electrically-conductive pad; and
a second electrically-insulating layer covering the electrically-conductive pad and covering the first electrically-insulating layer.

According to an embodiment, the electrically-conductive pad comprises aluminum.

According to an embodiment, the first electrically-insulating layer is made of a first material, for example of silicon oxynitride.

According to an embodiment, the second electrically-insulating layer is made of a second material, different from the first, for example of aluminum oxide.

According to an embodiment, the angle of inclination of each inclined side with respect to the surface is in the range from 250 to 50°.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1, FIG. 2, FIG. 3, FIG. 4, FIG. 5, FIG. 6, FIG. 7, FIG. 8, FIG. 9, FIG. 10, FIG. 11, and FIG. 12 are cross-section views illustrating structures obtained at the end of successive steps of an example of an electronic circuit manufacturing method;

FIG. 13 is a partial and simplified top view of the electronic circuit of FIG. 12;

FIG. 14, FIG. 15, FIG. 16, FIG. 17, FIG. 18, FIG. 19, FIG. 20, FIG. 21, and FIG. 22 are cross-section views illustrating structures obtained at the end of successive steps of an embodiment of an electronic circuit manufacturing method; and

FIG. 23 is a partial and simplified top view of the electronic circuit of FIG. 22.

### DETAILED DESCRIPTION

Like features have been designated by like references in the various figures. In particular, the structural and/or functional features that are common among the various embodiments may have the same references and may dispose identical structural, dimensional and material properties.

For clarity, those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%. Further, it is here considered that the terms “insulating” and “conductive” respectively signify “electrically insulating” and “electrically conductive”. Further, there is meant by “compound mainly made of a material” or “compound based on a material” that a compound comprises a proportion greater than or equal to 90% of said material, this proportion being preferably greater than 99%.

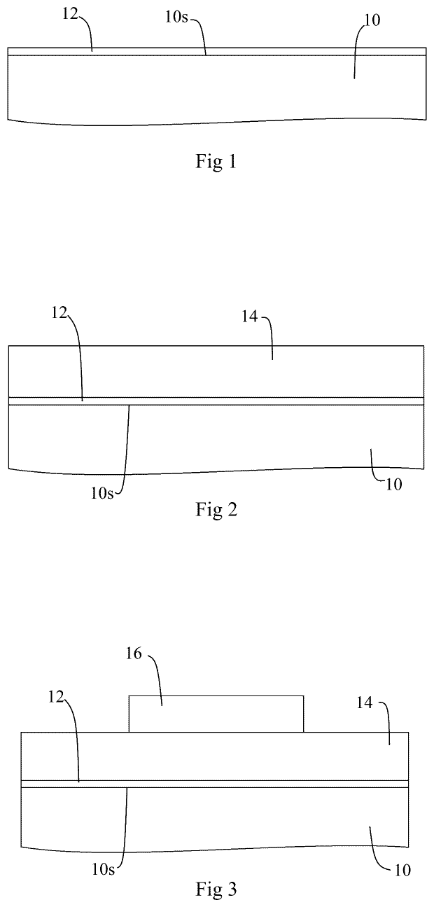

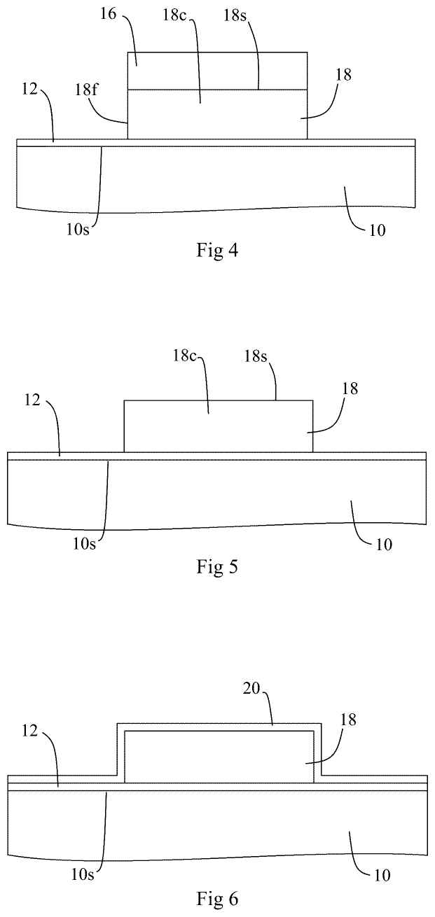

FIGS. 1 to 12 illustrate, schematically and partially, devices or structures obtained at the end of successive steps of an example of a method of manufacturing an electronic circuit comprising contact pads.

More particularly, FIG. 1 corresponds to an initial structure comprising a substrate 10 having a surface 10s. According to an embodiment, substrate 10 is made of a semiconductor material, for example a silicon substrate. According to an example, the contact pads are intended to be formed on the side of surface 10s, while an interconnection structure, not shown, is formed on substrate 10 on the side opposite to surface 10s. In this case, the surface 10s of semiconductor substrate 10 is covered with an insulating layer 12. According to an embodiment, insulating layer 12 has a thickness in the range from 200 nm to 15 μm. The insulating layer 12 may have a single-layer structure or a multilayer structure. According to an embodiment, insulating layer 12 is made of silicon oxide or of silicon nitride. According to another example, the interconnection structure is formed on substrate 10 on the side of surface 10s, and the contact pads are intended to be formed on the interconnection structure. The layer 12 illustrated in FIG. 1 then corresponds to the interconnection structure, which comprises a stack of insulating layers between which conductive tracks are provided, and through which conductive vias are provided.

FIG. 2 illustrates the structure obtained by a step of deposition of a conductive layer 14 on insulating layer 12. According to an embodiment, the thickness of conductive layer 14 is in the range from 200 nm to 4 μm, and is for example equal to approximately 2 μm. According to an embodiment, conductive layer 14 is based on a metallic material, and is for example based on aluminum. Conductive layer 14 may have a single-layer structure or a multilayer structure. In particular, conductive layer 14 may comprise an aluminum layer, resting on the side of substrate 10, on a barrier and/or bonding layer, for example made of tantalum nitride or of titanium, in direct physical contact with insulating layer 12. The aluminum layer may further be covered, on the side opposite to substrate 10, with a layer comprising a nitride, such as titanium nitride, or with silicon oxide. Conductive layer 14 may be deposited by a vapor deposition method.

FIG. 3 illustrates the structure obtained at the end of a step of forming of an etching mask 16 on conductive layer 14 at the locations where conductive layer 14 is to be kept.

FIG. 4 illustrates the structure obtained after an step of anisotropic etching of conductive layer 14 through etch mask 16. An anisotropic etching may be used. Contact pads 18 are then obtained, a single contact pad 18 being shown in FIG. 4. Each contact pad 18 comprises an upper surface 18s, preferably substantially planar and parallel to upper surface 10s, and sides 18f substantially orthogonal to upper surface 10s. Each contact pad 18 comprises a contacting area 18c. The contacting area 18c of each pad 18 is intended to be connected to an external device, for example by means of an electrically-conductive wire, for example a metal wire.

FIG. 5 illustrates the structure obtained at the end of a removal of etch mask 16. In FIG. 5, contact pad 18 is shown as covering surface 10s of the substrate.

FIG. 6 illustrates the structure obtained at the end of the step of forming of an insulating layer 20 over the entire structure shown in FIG. 5, and in particular on contact pad 18 and on insulating layer 12 around contact pad 18.

FIG. 7 illustrates the structure obtained after a step of forming of a resin layer 22 on insulating layer 20 and the forming, for each contact pad 18, of an opening 24 in resin layer 22 exposing the portion of insulating layer 20 covering the contacting area 18c of contact pad 18.

FIG. 8 illustrates the structure obtained at the end of a step of etching of insulating layer 20 in each opening 24 of resin layer 22 to expose, for each contact pad 18, the contacting area 18c of contact pad 18. During this step, resin layer 22 is used as an etch mask.

The etching implemented during this step is a reactive ion etching, also called ion bombardment etching, reactive dry etching, or dry etching. During the above-mentioned step, layers 20 and 22 are simultaneously consumed. The etching step is stopped, for example, when contact pads 18 are completely degraded in openings 24 and there remain no residues of insulating layer 20 on their surface. At this stage, a portion of resin layer 22 remains on the surface of insulating layer 20 outside of openings 24.

Advantageously, the etching exhibits a good selectivity over the material forming contact pad 18. As an example, when contact pad 18 is based on aluminum, the etch chemistry may comprise at least one gas containing fluorine, in particular tetrafluoromethane (CF₄) or trifluoromethane (CHF₃), argon (Ar), nitrogen (N₂), and optionally oxygen.

The etching by ion bombardment of layers 20 and 22 results in the forming of fibers or filaments 26 on the sides of insulating layer 20 and which may also extend over the sides of resin layer 22. Fibers or filaments 26 comprise non-volatile compounds based on fluorine and on aluminum, in particular aluminum fluoride (AlF₃), which are formed as a result of aluminum projections originating from contact pad 18.

Further, the reactive ion etching of layers 20 and 22 results in the presence of contaminants on the exposed contacting area 18c of contact pad 18, comprising, for example, fluorine- and aluminum-based compounds, in particular of AlₓO_{y}F_{z} type. The presence of contaminants is illustrated in FIG. 8 by an area 30 on the exposed surface of the contacting area 18c of contact pad 18.

FIG. 9 illustrates the structure obtained at the end of a step of removal of the remaining portion of resin layer 22 so as to free the upper surface of insulating layer 20 previously covered with resin layer 22.

At least part of fibers or filaments 26 may still be present after the step of removal of resin layer 22. Certain fibers or filaments 26 may even have fallen back onto the upper surface 18s of contact pad 18. Further, at least part of contaminants 30 may still be present on the contacting area 18c of contact pad 18 after the step of removal of resin layer 22.

FIG. 10 illustrates the structure obtained at the end of a step of removal of fibers or filaments 26 and of deposits 28. This removal step is for example carried out by dry etching, in particular by oxygen-based offset or non-offset reactive ion etching, or by wet etching, by means of an etching solution enabling to etch the material of fibers or filaments 26 and of deposits 28 selectively over the material of insulating layer 20 and the material of contact pad 18. The etching solution for example comprises hydrofluoric acid (HF) or also sulfuric acid (H₂SO₄).

FIG. 11 illustrates the structure obtained after a step of removal of contaminants 30 from the contacting area 18c of each contact pad 18. According to an embodiment, the removal of contaminants 30 is performed by an etching step. The implemented etching is, for example, a reactive ion etching using an argon ion beam.

FIG. 12 illustrates the structure obtained at the end of a step of forming of a protection layer 32 on the contacting area 18c of each contact pad 18. Protection layer 32 is, for example, a layer of alumina (Al₂O₃) obtained by a surface oxidation of aluminum. Protection layer 32 particularly aims at protecting contact pad 18 from moisture, in particular during a phase of storage of the electronic circuit.

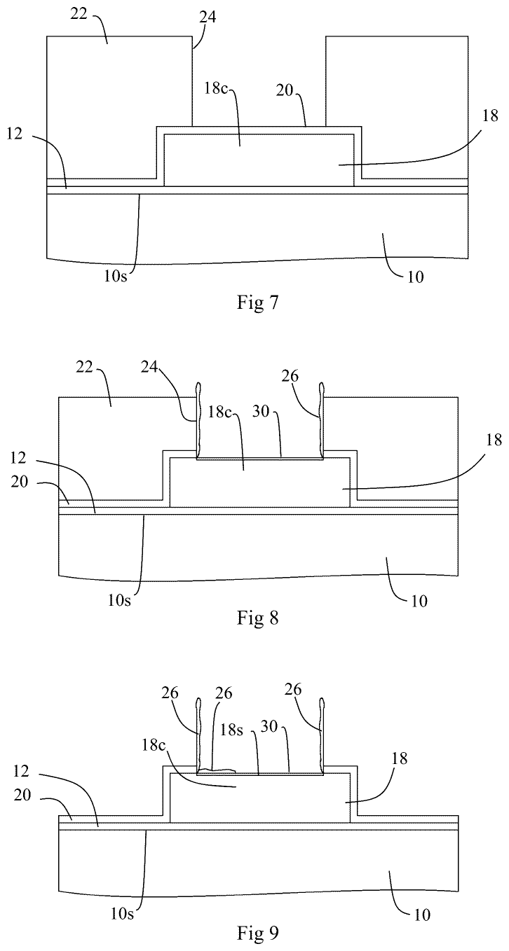

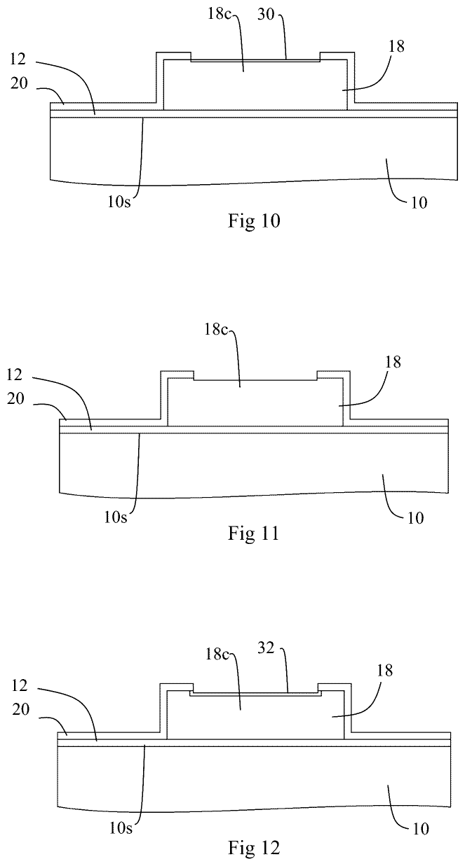

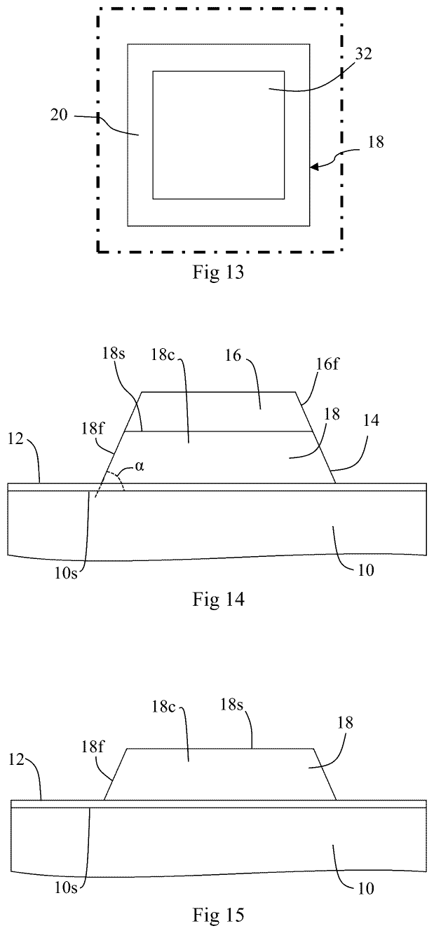

FIG. 13 is a partial and simplified top view of the electronic circuit of FIG. 12 in the case where contact pad 18 substantially corresponds to a parallelepiped with a square base.

A disadvantage of the previously-described example of a manufacturing method is that it may be difficult to remove all fibers or filaments 26 at the step previously described in relation with FIG. 9. Remaining fibers or filaments 26 may then disturbs the implementation of the subsequent steps of the method, for example the forming of protection layer 32. A degradation of contact pad 18 may then occur, making the electronic circuit unusable, for example by the forming of AlF₃ on the surface of the pads.

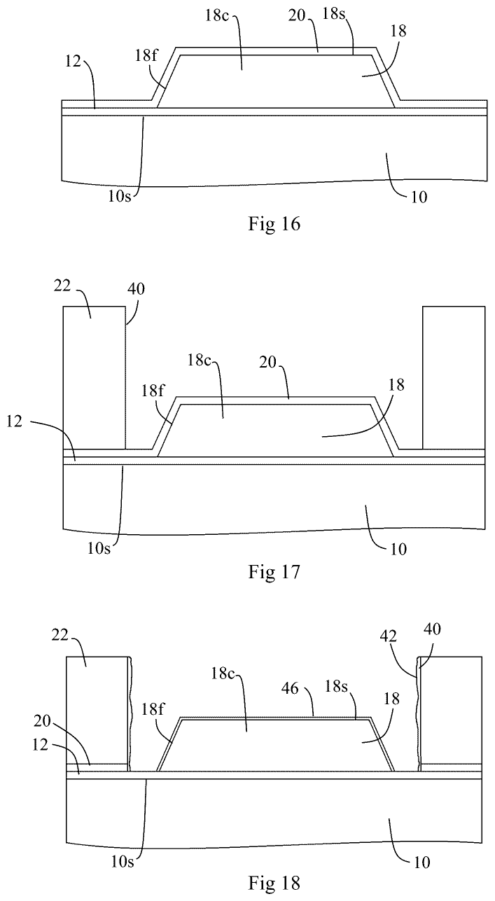

FIGS. 14 to 22 illustrate, schematically and partially, devices or structures obtained at the end of successive steps of an embodiment of an electronic circuit manufacturing method.

The initial steps of the method are identical to what has been previously described in relation with FIGS. 1 to 3.

FIG. 14 illustrates the structure obtained at the end of a step of etching of conductive layer 14 through etch mask 16 to form pad 18.

The plasma etching implemented to obtain the device illustrated in FIG. 14 consumes etch mask 16 and conductive layer 14. At the end of this etching step, contact pad 18 has an inclined (non-vertical) side 18f. The side 18f is a sidewall of the contact pad 18. As an example, the inclination of the sides 18f of contact pad 18 may be controlled, in particular, by a control of the ratio of the gases used in the plasma during the etching, an increase in the bias voltage of the reactor electrodes used to obtain the etch plasma, and/or the forming of inclined surfaces 16f in etch mask 16. According to an embodiment, the angle of inclination a of each side 18f with respect to surface 10s of substrate 10 is in the range from 25° to 50°, inclusive.

The chemical etching plasma used preferably comprises chlorine (Cl₂) or boron trichloride (BCl₃). As an example, the temperature of the material etched during this step is in the range from 30° C. to 50° C.

The above-mentioned etching is stopped when insulating layer 12 is exposed and slightly consumed by overetching. Contact pads 18 are then obtained, a single contact pad 18 being shown in FIG. 14. Each contact pad 18 comprises contacting area 18c, as previously described. At this stage, a portion of etch mask 16 remains on the upper surface 18s of contact pad 18.

FIG. 15 illustrates the structure obtained at the end of a step of removal of etch mask 16. Each contact pad 18 is now fully exposed.

FIG. 16 illustrates the structure obtained at the end of a step of forming of insulating layer 20 over the entire structure shown in FIG. 15. Thus, insulating layer 20 covers the upper surface 18s and the sides 18f of each contact pad 18, and further covers insulating layer 12 between contact pads 18. According to an embodiment, insulating layer 20 has a thickness in the range from 100 nm to 4 μm. Insulating layer 20 may have a single-layer structure or a multilayer structure. According to an embodiment, insulating layer 20 may be, for example, a bilayer formed of a nitride and of an oxide.

As an example, insulating layer 20 is deposited, by a method of conformal deposition on the upper surface of the structure illustrated in FIG. 15, for example by chemical vapor deposition, for example, a plasma-enhanced chemical vapor deposition (PECVD). As an example, the temperature during the forming of insulating layer 20 is in the range from 150° C. to 450° C., for example in the order of 400° C.

FIG. 17 illustrates the structure obtained at the end of a step of forming of resin layer 22 on insulating layer 20 and the forming, for each contact pad 18, of an opening 40 in resin layer 22 exposing the portion of insulating layer 20 covering the entire contact pad 18 and a portion of substrate 10 around contact pad 18. The dimensions of opening 40 are thus greater than the dimensions of the opening 24 previously described in relation with FIG. 7 for a contact pad having the same footprint on surface 10s. In one embodiment, the minimum distance between the wall of the opening 40 and the contact pad 18 is greater than a thickness of the insulating layer 20. For example, the minimum distance between the wall of opening 40 and contact pad 18 is greater than or equal to 1 μm for a small thickness of the layer 20 to be etched, for example, 100 nm. For a thickness of layer 20 in the order of 4 μm, this minimum distance will be higher, for example 8 μm. Resin layer 22 is for example deposited over the entire surface of insulating layer 20. Resin layer 22 has for example a thickness in the range from 900 nm to 5 μm. Openings 40 may be formed by photolithography steps.

FIG. 18 illustrates the structure obtained at the end of a step of etching of insulating layer 20, stopping in insulating layer 12 in controlled manner, in each opening 40 of resin layer 22 to entirely expose, for each contact pad 18, the upper surface 18s and the inclined sides 18f of contact pad 18 and a strip of the upper surface 10s of substrate 10 around contact pad 18. During this step, resin layer 22 is used as an etch mask.

The etching implemented during this step is a reactive ion etching, for example such as previously described in relation with FIG. 8. During the above-mentioned step, layers 20 and 22 are simultaneously consumed. The etching step is for example stopped when contact pads 18 are fully exposed and there remain no further residues of insulating layer 20 on their surface. At this stage, a portion of resin layer 22 remains at the surface of insulating layer 20 outside of openings 40.

The reactive ion etching of layers 20 and 22 results in the forming of fibers or filaments 42 which may contain, for example, silicon, aluminum, fluorine, oxygen, carbon. These fibers are formed on the sides of insulating layers 12 and 20, and may also extend over the sides of resin layer 22.

The composition of fibers or filaments 42 is different from that of the fibers or filaments 26 previously described in relation with FIG. 8. Indeed, since opening 40 is wider than contact pad 18, the non-volatile compounds which form fibers or filaments 42 are not in direct contact with the material forming contact pad 18, in particular aluminum, but with the material forming layer 12, so that fibers or filaments 42 comprise silicon- or fluorine-based compounds.

Further, the reactive ion etching of layers 20 and 22 results in the presence of contaminants on the upper surface 18s and the inclined side 18f of contact pad 18, comprising, for example, fluorine- and aluminum-based compounds, in particular of AlₓO_{y}F_{z} type. The presence of contaminants is illustrated in FIG. 18 by an area 46 on the upper surface of contact pad 18.

FIG. 19 illustrates the structure obtained at the end of a step of removal of the remaining portion of resin layer 22 so as to free the upper surface of insulating layer 20 previously covered with resin layer 22. This removal step is for example carried out by oxygen-based dry etching performed by means of an offset or non-offset plasma enabling to etch the material of resin layer 22 selectively over the material of insulating layer 20 and the material forming contact pads 18.

At least part of fibers or filaments 42 may still be present after the step of removal of resin layer 22 from insulating layer 20. Preferably, for each contact pad 18, the distance between the walls of opening 40 and contact pad 18 is sufficiently large to prevent fibers or filaments 42 from falling back and coming into contact with contact pad 18.

FIG. 20 illustrates the structure obtained at the end of a step of removal of fibers or filaments 42. This removal step is for example carried out by wet etching, by means of an etching solution enabling to selectively etch the material of fibers or filaments 42 over the material of insulating layer 20 and the material forming contact pads 18. The wet etching solution comprises, for example, hydrofluoric acid (HF) or sulfuric acid (H₂SO₄). Advantageously, since fibers or filaments 42 are not based on fluorine and on the material forming contact pad 18 but based on the material, for example, silicon oxide, forming layer 12, the removal of fibers 42 is strongly facilitated.

FIG. 21 illustrates the structure obtained at the end of a step of removal of contaminants 46 from each contact pad 18. According to an embodiment, the removal of contaminants 46 is performed by an etching step. The implemented etching is for example a reactive ion etching, using an argon ion beam, or a wet etching, for example with H₂SO₄. As compared with orthogonal sides, the inclination of the sides 18f of contact pad 18 advantageously enables to facilitate the removal of contaminants 46 from these sides 18f, particularly in the case of the use of an argon ion beam.

FIG. 22 illustrates the structure obtained at the end of a step of forming of a protection layer 48 over the entire upper surface of each contact pad 18. Protection layer 48 is, for example, a layer of alumina (Al₂O₃). According to an embodiment, protection layer 48 has a thickness in the range from 1 nm to 5 nm. Protection layer 48 particularly aims at protecting contact pad 48 from moisture.

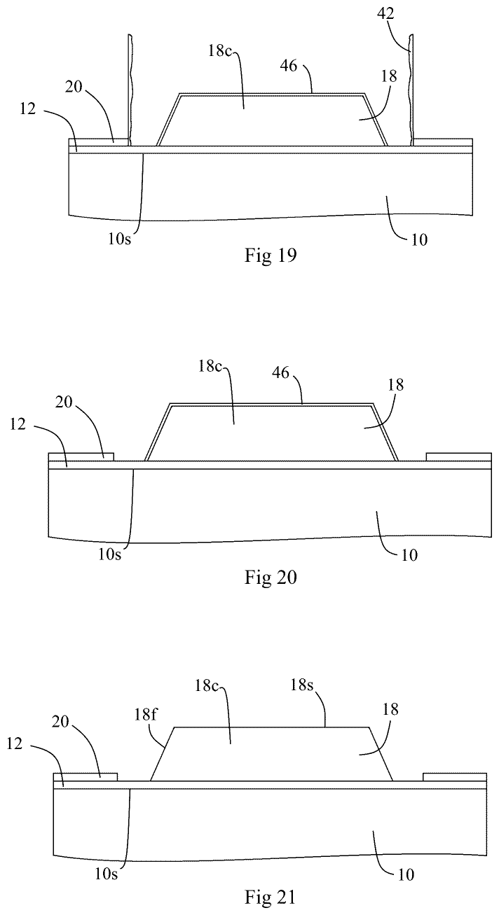

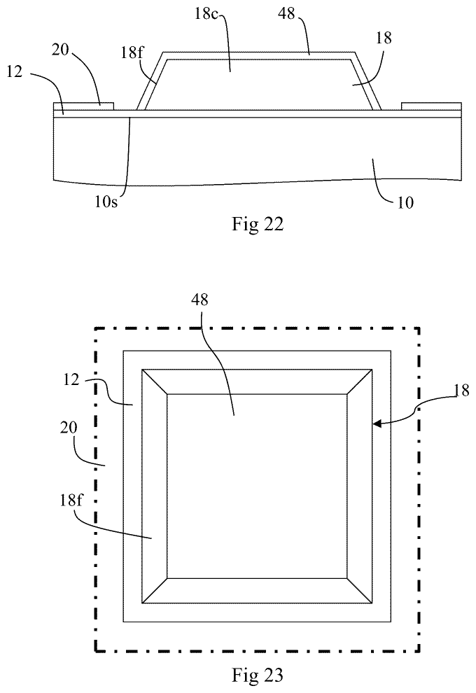

FIG. 23 is a partial and simplified top view of the electronic circuit of FIG. 22, in the case where contact pad 18 substantially corresponds to a truncated pyramid with a square base.

Various embodiments and variants have been described. Those skilled in the art will understand that certain features of these various embodiments and variants may be combined, and other variants will occur to those skilled in the art. In particular, the described embodiments are not limited to the above-mentioned examples of dimensions and of materials.

Finally, the practical implementation of the described embodiments and variants is within the abilities of those skilled in the art based on the functional indications given hereabove.

A method of manufacturing an electronic circuit may be summarized as including the following steps, in the order: a) forming on a semiconductor substrate (10) including a surface (10s) of at least one electrically-conductive pad (18) extending over the surface (10s) and having sides (18f) inclined with respect to the surface (10s); b) forming of a first electrically-insulating layer (20) on the electrically-conductive pad (18); c) deposition of a resin layer (22) and forming of an opening (40) in the resin layer exposing the entire electrically-conductive pad (18); d) plasma etching of the first electrically-insulating layer (20) in the opening (40), which results in the forming of first compounds (42) on the etched edges of the first electrically-insulating layer (20) and of second compounds (46) on the electrically-conductive pad (18); e) removal of the resin layer (22); f) removal of the first compounds (42); g) removal of the second compounds (46); and g) forming of a second electrically-insulating layer (48) on the electrically-conductive pad (18).

The electrically-conductive pad (18) comprises aluminum.

At step d), the plasma comprises fluorine.

Step g) comprises a reactive ion etching using an argon ion beam.

The minimum distance between the wall of the opening (40) and the electrically-conductive pad (18) is greater than the thickness of the first electrically-insulating layer (20).

The first electrically-insulating layer (20) is made of a first material, for example of silicon oxynitride (SiON).

The second electrically-insulating layer (48) is made of a second material, different from the first material, for example of aluminum oxide.

The angle of inclination of each inclined side (18f) with respect to the surface (10s) is in the range from 250 to 50°.

An electronic circuit may be summarized as including: a semiconductor substrate (10) comprising a surface (10s); an electrically-conductive pad (18) extending over the surface (10s) and having sides (18f) inclined with respect to the surface (10s); a first electrically-insulating layer (20) on the surface (10s) which surrounds the electrically-conductive pad (18) and does not cover the electrically-conductive pad (18); and a second electrically-insulating layer (48) covering the electrically-conductive pad (18) and covering the first electrically-insulating layer (20).

The electrically-conductive pad (18) comprises aluminum.

The first electrically-insulating layer (20) is made of a first material, for example of silicon oxynitride (SiON).

The second electrically-insulating layer (48) is made of a second material, different from the first material, for example of aluminum oxide.

The angle of inclination of each inclined side (18f) with respect to the surface (10s) is in the range from 250 to 50°.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an electronic circuit, the method comprising:
forming, on a surface of a semiconductor substrate, at least one electrically-conductive pad having sides inclined with respect to the surface;
forming a first electrically-insulating layer on the electrically-conductive pad;
forming a resin layer on the surface of the semiconductor substrate;
forming an opening in the resin layer exposing the entire electrically-conductive pad;
plasma etching the first electrically-insulating layer in the opening, which results in forming of first compounds on etched edges of the first electrically-insulating layer and of second compounds on the electrically-conductive pad;
removing the resin layer;
removing the first compounds;
removing the second compounds; and
forming a second electrically-insulating layer on the electrically-conductive pad.

2. The method according to claim 1, wherein the electrically-conductive pad includes aluminum.

3. The method according to claim 1, wherein plasma for the plasma etching includes fluorine.

4. The method according to claim 1, wherein removing the second compounds includes a reactive ion etching using an argon ion beam.

5. The method according to claim 1, wherein a minimum distance between a wall of the opening and the electrically-conductive pad is greater than a thickness of the first electrically-insulating layer.

6. The method according to claim 1, wherein the first electrically-insulating layer is made of a first material including silicon oxynitride (SiON).

7. The method according to claim 6, wherein the second electrically-insulating layer is made of a second material different from the first material and including aluminum oxide.

8. The method according to claim 1, wherein an angle of inclination of each of the sides inclined with respect to the surface is in a range from 250 to 50°.

9. An electronic circuit, comprising:
a semiconductor substrate including a surface;
an electrically-conductive pad extending over the surface and having sides inclined with respect to the surface;
a first electrically-insulating layer on the surface which surrounds the electrically-conductive pad and does not cover the electrically-conductive pad; and
a second electrically-insulating layer covering the electrically-conductive pad, wherein an angle of inclination of each of the sides with respect to the surface is in the range from 250 to 50°.

10. The electronic circuit according to claim 9, wherein the electrically-conductive pad includes aluminum.

11. The electronic circuit according to claim 9, wherein the first electrically-insulating layer is made of a first material including silicon oxynitride.

12. The electronic circuit according to claim 11, wherein the second electrically-insulating layer is made of a second material different from the first material and including aluminum oxide.

13-20. (canceled)

21. The electronic circuit according to claim 9, wherein a minimum distance between an end of the first electrically-insulating layer proximal to the electrically-conductive pad and the inclined side of the electrically-conductive pad is greater than the thickness of the first electrically-insulating layer.

22. An electronic circuit comprising:
a semiconductor substrate comprising a surface;
an electrically-conductive pad extending over the surface and having sides inclined with respect to the surface;
a first electrically-insulating layer on the surface which surrounds the electrically-conductive pad and does not cover the electrically-conductive pad; and
a second electrically-insulating layer covering the electrically-conductive pad,
wherein a minimum distance between an end of the first electrically-insulating layer proximal to the electrically-conductive pad and the inclined side of the electrically-conductive pad is greater than the thickness of the first electrically-insulating layer.

23. The electronic circuit according to claim 22, wherein the minimum distance is greater than or equal to 1 μm for a thickness of the first electrically-insulating layer equal to about 100 nm.

24. The electronic circuit according to claim 22, wherein the minimum distance is greater than or equal to 8 μm for a thickness of the first electrically-insulating layer equal to about 4 μm.

25. The electronic circuit according to claim 22, wherein the first electrically-insulating layer is a bilayer formed of a nitride and of an oxide.

26. The electronic circuit according to claim 22, wherein the second electrically-insulating layer has a thickness in the range from 1 nm to 5 nm.

27. The electronic circuit according to claim 22, wherein the second electrically-insulating layer is made of alumina (Al₂O₃).

28. The electronic circuit according to claim 22 wherein the electrically-conductive pad comprises an aluminum layer interposed between a first barrier layer arranged below and in direct contact with the aluminum layer and a second barrier layer arranged above and in direct contact with the aluminum layer,
wherein the first barrier layer is made of a material selected in the group: tantalum, titanium, tantalum nitride, titanium nitride, or combinations thereof, and
wherein the second barrier layer is made of a material selected in the group: titanium nitride, silicon oxide, or combinations thereof.
